(19) United States
(12) Patent Application Publication
(10) Pub. No.: US 2021/0005341 A1
(43) Pub. Date: Jan. 7, 2021

(54) Manipulating Properties of Matter in an Excited State

(71) Applicant: Patrick Dean Cummins, Louisville, KY (US)

(72) Inventor: Patrick Dean Cummins, Louisville, KY (US)

(21) Appl. No.: 16/459,580

(22) Filed: Jul. 1, 2019

(51) Int. Cl. G21K 1/093; G06K 7/015; G21K 1/00

(52) U.S. Cl. CPC G21K 1/093; G21K 1/003; G06K 7/015

(57) ABSTRACT

Implementations set forth herein relate to a system for manipulating mass. The system can include one or more radiation emitting apparatuses and a material chamber that includes a material. The material can be caused to experience a centrifugal force according to a motion of the material chamber. While the material is experiencing the centrifugal force, the one or more radiation emitting apparatuses can cause the material to increase in temperature and experience an electromagnetic force. The combination of forces can affect properties of the material and/or any other materials that can be in direct and/or indirect contact with the material.

### TECHNICAL FIELD

Implementations set forth herein relate to systems, methods, and/or apparatuses for manipulating materials using electromagnetic waves, inductive heating, and/or mechanical motion.

### BACKGROUND

Materials can be manipulated through a variety of methods for performing a variety of different functions. For instance, new materials are often manufactured by mixing materials at different temperatures and/or pressures in order to generate new materials with certain properties. However, without further manipulation, certain properties may not be exhibited by a mixture of materials, thereby bypassing any opportunity to effectuate material properties that can provide more efficient uses of various types of energy.

### SUMMARY

The present disclosure is generally directed to methods, systems, apparatuses, and computer-readable media (transitory and/or non-transitory) for controlling and/or providing a system for manipulating mass. In some implementations, a system is set forth as including a material chamber configured to at least partially envelope a material. The system can also include a motor that is operatively coupled to the material chamber, wherein the motor is configured to directly or indirectly cause the material chamber to rotate. The system can also include one or more radiation emitting apparatuses configured to emit a first electromagnetic field and a second electromagnetic field simultaneous to the motor causing the material chamber to rotate, wherein the first electromagnetic field causes the material within the material chamber to be pulled toward or away from an outer perimeter of the material chamber simultaneous to the material chamber rotating, and wherein the second electromagnetic field causes the material within the material chamber to exhibit an increase in temperature simultaneous to the material chamber rotating.

In some implementations, the outer perimeter is circular and the one or more radiation emitting apparatuses include a first radiation emitting apparatus and a second radiation emitting apparatus. In some implementations, the first radiation emitting apparatus is located outside of an outer radius of the material chamber and the second radiation emitting apparatuses is located outside of the outer radius of material chamber or within the outer radius of the material chamber. In some implementations, the outer perimeter is circular and the one or more radiation emitting apparatuses include a first radiation emitting apparatus and a second radiation emitting apparatus. In some implementations, the first radiation emitting apparatus is located within of an outer radius of the material chamber and the second radiation emitting apparatuses is located within the outer radius of the material chamber. In some implementations, the second electromagnetic field oscillates according to an input to the second radiation emitting apparatus and causes the material to exhibit the increase in temperature. In some implementations, the material is a fluid that includes metal particles. In some implementations, the material chamber includes an inner volume that has a torus shape and the material occupies at least a portion of the inner volume.

In other implementations, a method implemented by one or more processors for operating a system for manipulating mass is set forth as including operations such as causing a material chamber of the system to spin, wherein a material occupies an inner volume of the material chamber and the material experiences a centrifugal force as a result of the spin of the material chamber. The method can further include an operation of causing, while the material chamber is spinning, one or more radiation emitting apparatuses to increase a temperature of the material within the material chamber, wherein the increase in temperature of the material occurs when the material is experiencing the centrifugal force resulting from the spinning of the material chamber. The method can further include an operation of causing, while the material is experiencing the increase in temperature and the centrifugal force, the one or more other radiation emitting apparatuses to provide an electromagnetic field that causes at least a portion of the material within the material chamber to experience an electromagnetic force, wherein the electromagnetic force causes the material to move toward an outer perimeter of the material chamber or toward an inner perimeter of the material chamber.

In some implementations, the outer perimeter is circular and the one or more radiation emitting apparatuses include a first radiation emitting apparatus and a second radiation emitting apparatus. In some implementations, the first radiation emitting apparatus is located outside of an outer radius of the material chamber and the second radiation emitting apparatuses is located outside of the outer radius of material chamber or within the outer radius of the material chamber. In some implementations, the outer perimeter is circular and the one or more radiation emitting apparatuses include a first radiation emitting apparatus and a second radiation emitting apparatus. In some implementations, the first radiation emitting apparatus is located within of an outer radius of the material chamber and the second radiation emitting apparatuses is located within the outer radius of the material chamber or within the outer radius of the material chamber. In some implementations, the second electromagnetic field oscillates according to an input to the second radiation emitting apparatus and causes the material to exhibit the increase in temperature. In some implementations, the second electromagnetic field causes the material to emit visible light. In some implementations, the material is a fluid that includes metal particles. In some implementations, the material chamber includes an inner volume that has a torus shape and the material occupies at least a portion of the inner volume.

In yet other implementations, a non-transitory computer readable storage medium is set forth. The non-transitory computer-readable medium can be configured to store instructions that, when executed by a processor included in a computing device, cause the computing device to perform operations that include: causing a material chamber of the system to spin, wherein a material occupies an inner volume of the material chamber and the material experiences a centrifugal force as a result of the spin of the material chamber. The operations can further include an operation of causing, while the material chamber is spinning, one or more radiation emitting apparatuses to increase a temperature of the material within the material chamber, wherein the increase in temperature of the material occurs when the material is experiencing the centrifugal force resulting from the spinning of the material chamber. The operations can further include an operation of causing, while the material is experiencing the increase in temperature and the centrifugal force, the one or more other radiation emitting apparatuses to provide an electromagnetic field that causes at least a portion of the material within the material chamber to experience an electromagnetic force, wherein the electromagnetic force causes the material to move toward an outer perimeter of the material chamber or toward an inner perimeter of the material chamber.

In some implementations, the outer perimeter is circular and the one or more radiation emitting apparatuses include a first radiation emitting apparatus and a second radiation emitting apparatus, and the first radiation emitting apparatus is located outside of an outer radius of the material chamber and the second radiation emitting apparatuses is located outside of the outer radius of material chamber or within the outer radius of the material chamber. In some implementations, the outer perimeter is circular and the one or more radiation emitting apparatuses include a first radiation emitting apparatus and a second radiation emitting apparatus, and the first radiation emitting apparatus is located within of an outer radius of the material chamber and the second radiation emitting apparatuses is located within the outer radius of the material chamber or within the outer radius of the material chamber.

In some implementations, second electromagnetic field oscillates according to an input to the second radiation emitting apparatus and causes the material to exhibit the increase in temperature. In some implementations, the second electromagnetic field causes the material to emit visible light. In some implementations, the material is a fluid that includes metal particles. In some implementations, the material chamber includes an inner volume that has a torus shape and the material occupies at least a portion of the inner volume.

### BRIEF DESCRIPTION OF THE DRAWINGS

FIG. 1A and FIG. 1B illustrate perspective views of a system for manipulating mass.

FIG. 2A and FIG. 2B illustrate views of a system for manipulating mass.

FIG. 3A and FIG. 3B illustrate views of a system for manipulating mass, such as those described herein.

FIG. 4A, FIG. 4B, FIG. 4C, and FIG. 4D illustrate a views of an atom of material being affected by a system for manipulating mass.

FIG. 5 illustrates a method for controlling a system for manipulating mass.

FIG. 6 is a block diagram of an example computer system.

### DETAILED DESCRIPTION

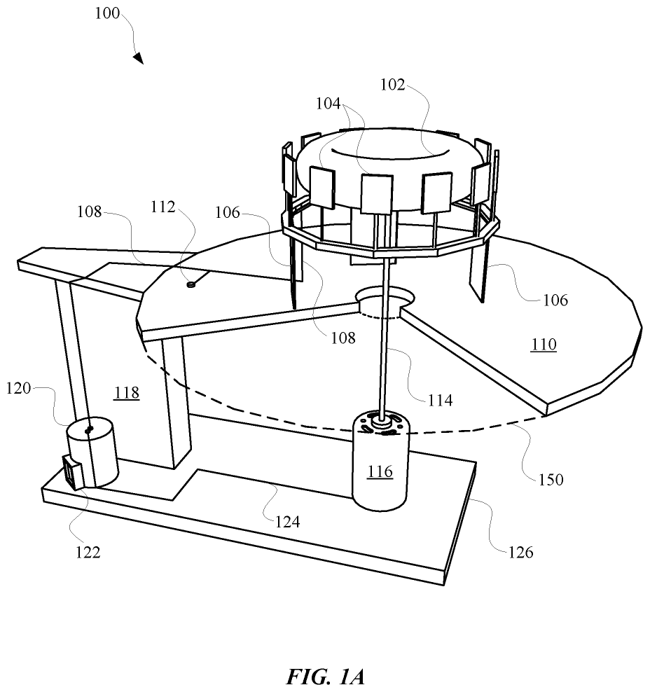

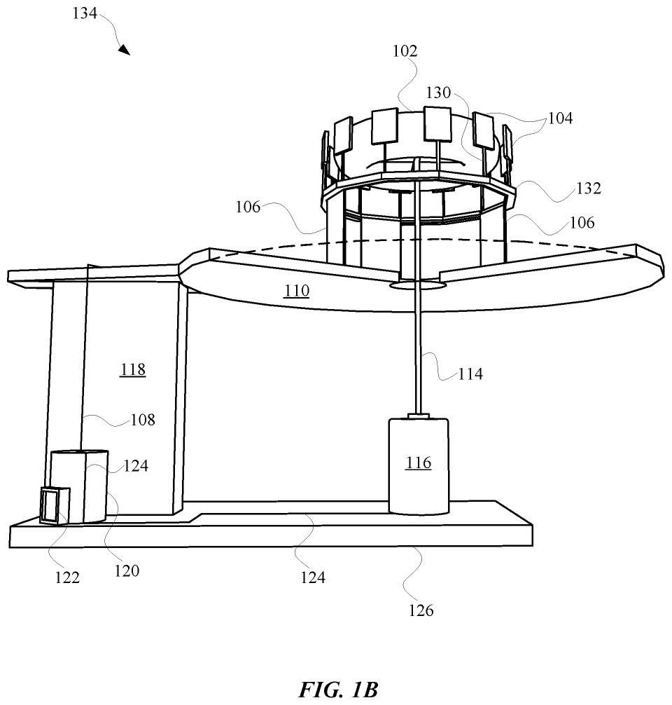

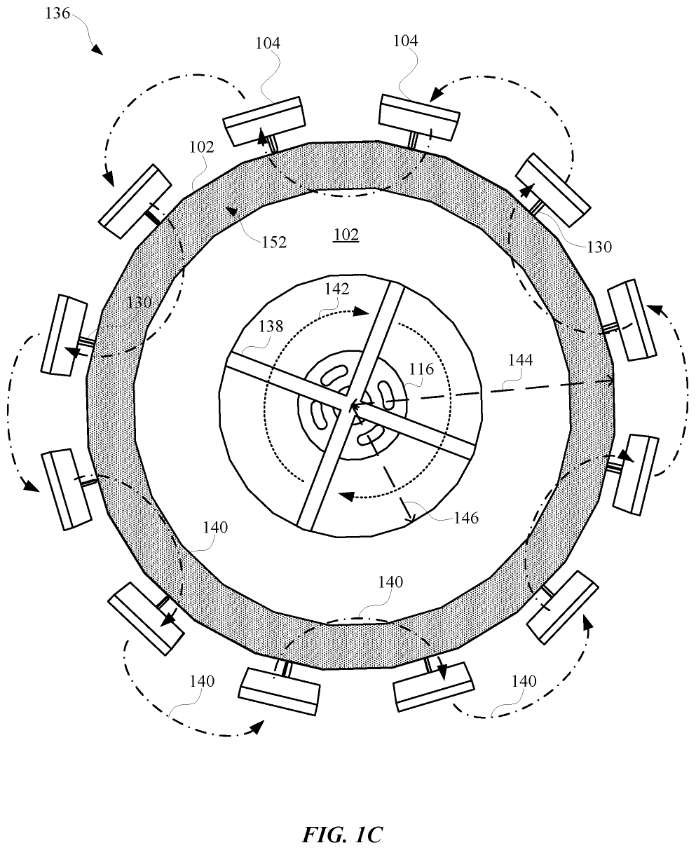

FIG. 1A illustrates a perspective view 100 of a system for manipulating mass. The system can include a material chamber 102 that can retain a volume of mass, and spin according to a motion of a motor 116. The mass can be a solid, liquid, gas, plasma, and/or any combination thereof, and/or any material capable of being retained within a volume. For instance, the mass can be, but is not limited to, a melted liquid metal alloy. The mass can be in a liquid state when, or as a result of, being influenced by a radiation emitting apparatus 104. The radiation emitting apparatus 104 can operate to provide one or more different types of radiation, which can influence the mass contained within the material chamber 102. For instance, each radiation emitting apparatus 104 can receive one or more signals over one or more wires 108, which are connected between a power system 120 and the radiation emitting apparatuses 104. The power system 120 can provide the radiation emitting apparatuses 104 with one or more alternating current signals that can cause each radiation emitting apparatus 104 to provide an electromagnetic field that can influence the mass retained within the material chamber 102. In some implementations, the electromagnetic field can cause at least some amount of atoms of the mass within the material chamber 102 to oscillate rapidly and, as a result, increase in temperature. For instance, the electromagnetic field can be an electromagnet field that rapidly oscillates according to, and/or close to, a harmonic frequency, or multiple harmonic frequencies, of the mass within the material chamber 102. In some implementations, the increase in temperature of the mass within the material chamber 102 can cause the mass to emit visible light (e.g., when the mass within the material chamber 102 becomes a glowing molten metal alloy), simultaneous to the material chamber 102 spinning according to a motion of the motor 116.

The power system 120 can provide other signals to the radiation emitting apparatuses 104 via the wires 108, or wirelessly, for influencing an electric and/or a magnetic polarity of a majority of the atoms of the mass. Specifically, the other signals can influence the mass when a temperature of the mass has been increased to a point at, or above, a temperature where the mass is emitting visible light and/or any other radiation. The other signals can cause the mass within the material chamber 102 to be attracted to the radiation emitting apparatuses 104, at least based on a magnetic field being provided by the radiation emitting apparatuses 104. For example, the radiation emitting apparatuses 104 can provide another magnetic field that causes the mass to be attracted to the source (e.g., the radiation emitting apparatuses 104) of the other signals.

Alternatively, or additionally, other radiation emitting apparatuses can be disposed with an inner radius (e.g., at least partially surrounded by a portion of the material chamber 102 that encircles a center point surrounded by the material chamber 102) of the material chamber 102, and other signals from the other radiation emitting elements can pull the mass toward a center of the material chamber 102 while the atoms of the mass have an increased temperature, and are spinning outwardly, away from the center, according to inertia and/or a motion of the motor 116.

The spinning of the material chamber 102 can be caused by a motor 116 that includes a shaft 114, which extends from a body of the motor 116 and connects directly and/or indirectly to one or more portions of the material chamber 102. The motor 116 can be mounted onto a base 126 that can extend parallel to a radius of the material chamber 102. In some implementations, wires 124 for powering the motor 116 can extend along the base 126 from the power system 120. The power system 120 can include a control panel 122 through which a user can control the system for manipulating mass. Furthermore, the power system 120 can be connected to wires 108 that extend from the power system 120 to an interference shield 110 and/or the radiation emitting apparatuses 104.

The interference shield 110 can be an optional portion of the system and can operate to limit an amount of electromagnetic interference that can occur between the motor 116 and the electromagnets 104. In FIG. 1A, a hidden view 150 of the interference shield 110 is provided in order to illustrate how the interference shield 110 can separate the motor 116 from the radiation emitting apparatuses 104. In some implementations, wires 108 from power system 120 can be connected to the interference shield 110 at connection 112, and provide a signal to the interference shield 110 that is different from a signal provided to the motor 116 and/or the electromagnets 104. In some implementations, the interference shield 110 can operate as a Faraday cage, thereby acting as a source for an electric field that mitigates electromagnetic interference between the motor 116 and the electromagnets 104. The signal provided to the interference shield 110 can be an alternating current signal and/or a direct current signal. In some implementations, a frequency of an alternating current signal provided to the interference shield 110 can be proportional to a frequency of a signal provided to the motor 116 and/or a frequency of a signal provided to the electromagnets 104.

The interference shield 110 can be mounted to a structure 118 that stabilizes the interference shield 110 between the motor 116 and the radiation emitting apparatuses 104. Alternatively, or additionally, mounts 106 can further displace the radiation emitting apparatuses 104 and/or the material chamber 102 from the interference shield 110. In some implementations, an outer diameter of the material chamber 102 can be greater than a diameter of the motor 116 in order to minimize interference between an electromagnetic field generated by the motor 116 and an electromagnetic field generated by the material chamber 102 and/or the radiation emitting apparatuses 104. For instance, an electromagnetic field can be generated at the material chamber 102 when a metal has been heated to a liquid phase and is emitting electromagnetic radiation, while the motor 116 is causing the material chamber 102 to rotate. Such motion can mimic the molten metal core of planet Earth, which provides a source of an electromagnetic field that surrounds the planet Earth. In some implementations, each radiation emitting apparatus of the radiation emitting apparatuses 104 can include one or more electromagnetic coils that receive a current signal from the power system 120 and provide an electromagnetic field that can influence material flowing within the material chamber 102, and any electromagnetic field created by that material flowing within the material chamber 102.

FIG. 1B illustrates a perspective view 134 of the system for manipulating mass. The perspective view 134 shows how mounts 106 can support a bracket 132, which the radiation emitting apparatuses 104 can be attached to. Furthermore, the bracket 132 can be connected to one or more supports 130, which can be attached to the radiation emitting apparatuses 104. In some implementations, the motor 116 can extend at least partially through the material chamber 102, and the radiation emitting apparatuses 104 can be disposed about a circumference that is greater than a circumference of the material chamber 102. Alternatively, or additionally, the radiation emitting apparatuses 104 can be disposed within a circumference defined by an innermost surface of the material chamber 102. Additionally, or alternatively, the radiation emitting apparatuses 104 can be disposed about a first circumference that is within an inner most circumference of the material chamber 102, and can also be disposed about a second circumference that is outside an outer most circumference of the material chamber 102.

FIG. 1C illustrates a perspective view 136 of at least a portion of the system for manipulating mass depicted in FIG. 1A and FIG. 1B. Specifically, FIG. 1C illustrates electromagnetic field(s) 140 being emitted by the radiation emitting apparatuses 104 and interacting with atoms 152 in the material chamber 102. For instance, an electromagnetic field 140 can be emitted by the radiation emitting apparatuses 104, and can magnetically attract atoms 152 that are flowing within the material chamber 102. Furthermore, in some implementations, another electromagnetic field can be emitted by the radiation emitting apparatuses 104 for causing the atoms 152 flowing within the material chamber 102 to heat up. Simultaneous to the electromagnetic field 140 being emitted by the radiation emitting apparatuses 104 and the atoms 152 flowing within the material chamber 102 heating up, the motor 116 can cause the material chamber 102 to spin. As a result, the atoms 152, which can be part of a metal and/or metal alloy, flowing within the material chamber 102 can: (1) enter a glowing state due to their temperature, (2) be forced toward an outer area of material chamber 102 by inertia created by a motion 142 of the motor 116, and (3) be pulled against the outer area of the material chamber 102 by the electromagnetic field 140 being emitted by the radiation emitting apparatuses 104 (where line 144 represents an outer radius of the material chamber and line 146 represents an inner radius of the material chamber).

The forces applied to these atoms 152 are set forth to modify a density of nuclei of the atoms 152, causing the atoms 152 to exhibit different properties compared to when the atoms 152 are not receiving such forces. Additionally, or alternatively, when radiation emitting apparatuses 104 are disposed within a center area of the material chamber 102, the material chamber 102 can be caused to spin according to a motion of the motor 116, and the atoms 152 can be caused to heat up based on radiation from the radiation emitting apparatuses 104. Furthermore, the radiation emitting apparatuses 104 disposed within the center area of the material chamber 102 can cause the atoms 152 to be attracted to the center area according to a magnetic field emitted by the radiation emitting apparatuses 104. As a result, the atoms 152, which can be part of a metal and/or metal alloy, flowing within the material chamber 102 can: (1) enter a glowing state due to their temperature, (2) be forced against an outer area of material chamber 102 by inertia created by a motion 142 of the motor 116, and (3) be pulled toward the inner area of the material chamber 102 by an electromagnetic field being emitted by the radiation emitting apparatuses 104 disposed within the center area of the material chamber 102. The forces applied to these atoms 152 are set forth to modify a density of nuclei of the atoms 152, causing the atoms 152 to exhibit different properties compared to when the atoms 152 are not receiving such forces. Such different properties can enable more efficient uses of energy, such as by overcoming gravity, thereby allowing materials, and/or any other contacting material, to be transferred more readily and more efficiently.

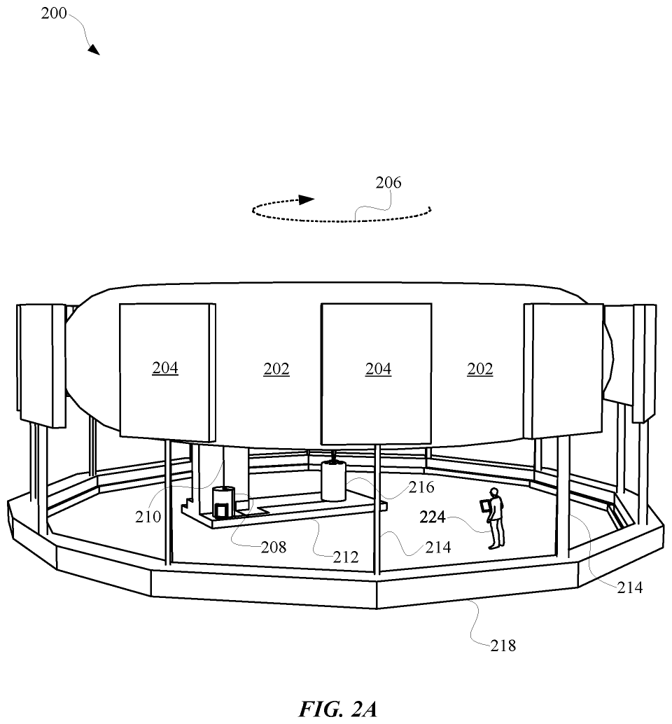

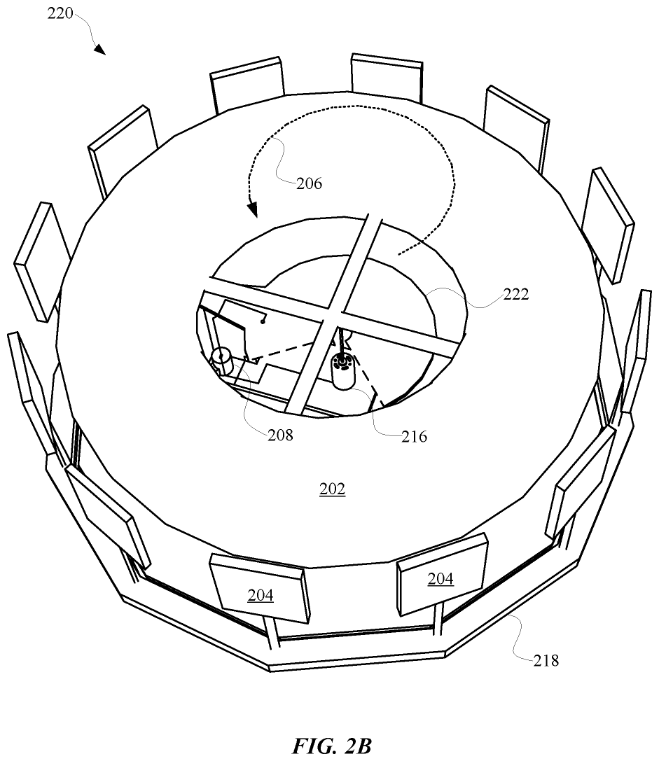

FIG. 2A and FIG. 2B illustrate a view 200 and a view 220 of a system for manipulating mass, which can be controlled by a user 224. The system can include a material chamber 202 for containing one or more different types of materials that can be experience centrifugal forces when the material chamber 102 is spinning in a direction 206 according to an operation of a motor 216. The motor 216 can be powered by a power system 208, which can provide one or more types of current to the motor 216, an optional interference shield 222, and one or more radiation emitting apparatuses 204. The radiation emitting apparatuses 204 can include one or more different types of coils for providing one or more different types of electromagnetic fields for manipulating the material within the material chamber 202. Each radiation emitting apparatus 204 can be mounted on a mount 214 that is attached to a bracket 132. In some implementations, the motor 216 and power system 208 can be mounted on a base 212, and one or more connections 210 can extend along the base 212 in order to provide power to the motor 216, the radiation emitting apparatuses 204, and/or the interference shield 222.

In some implementations, the interference shield 222 can be an optional portion of the system that limits an amount of electromagnetic interference between the motor 216 and one or more of the radiation emitting apparatuses 104 and/or the material chamber 202. For example, the motor 216 can operate according to an alternating current signal from the power system 208, and the one or more radiation emitting apparatuses 204 can operate according to the same and/or one or more different alternating current signals. For instance, each radiation emitting apparatuses 104 can include multiple electromagnetic devices (e.g., a coil that includes a conductor that is coated and/or a conductor made of magnetic wire), and each electromagnetic device of the multiple electromagnetic devices can receive a different current signal from the power system 208. As an example, a first electromagnetic device can receive a first current signal and a second electromagnetic device can receive a second current signal. The first current signal can be characterized as having a frequency X, and the second current signal can have another frequency Y, which can be less than, equal to, or greater than the frequency X. Additionally, or alternatively, the first current signal can have a VAC (Volts Alternating Current) value of A, and the second current signal can have another VAC value of B, which can be less than, equal to, or greater than the value A.

In some implementations, the first current signal received by the first electromagnetic device can be a direct current signal having a voltage K, where K is any number, and the second current signal received by the second electromagnetic device can be an alternating current signal having a frequency of M, where M is any number, and a VAC value of N, where N is any value. The first current signal can create first electromagnetic field via the radiation emitting apparatuses 204 that causes the material in the material chamber 202 to be forced away from a center area of the material chamber 202 or forced toward the center area of the material chamber 202, depending on a placement of the radiation emitting apparatuses 204. The second current signal can create a second electromagnetic field via the radiation emitting apparatuses 204 that causes the material in the material chamber 202 to increase in temperature. This increase in temperature can be caused by oscillations of the second electromagnetic field causing rapid movement of the particles of the material in the material chamber 202. The second electromagnetic field can cause the material to increase in temperature and enter an excited state in which visible light is emitted from the material. Furthermore, when the material is in the excited state, the material chamber 202 can be rotating according a motion of the motor 216, and the first electromagnetic field can be pulling the material toward or away from a center area of the material chamber 202. The combination of these forces can cause the material in the material chamber 202 to exhibit properties that the material would not otherwise exhibit. Furthermore, such properties can be useful for mitigating energy waste that might otherwise be employed when manipulating other materials to exhibit similar properties.

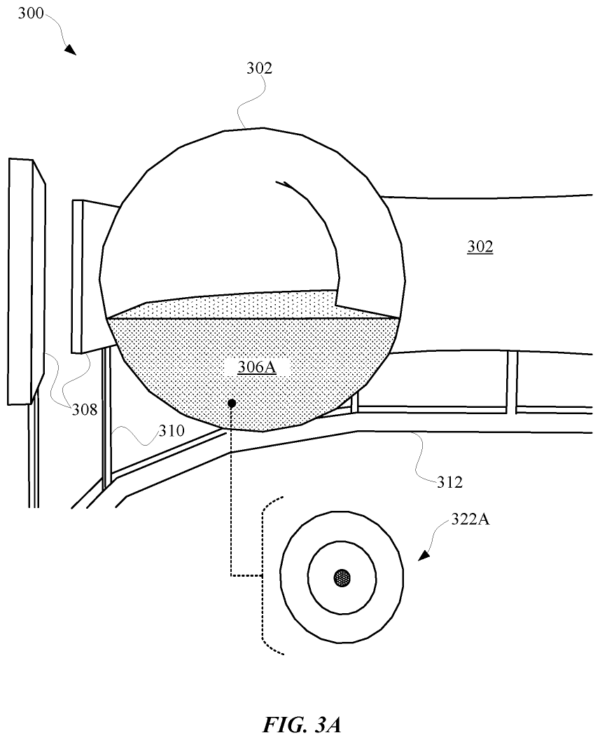

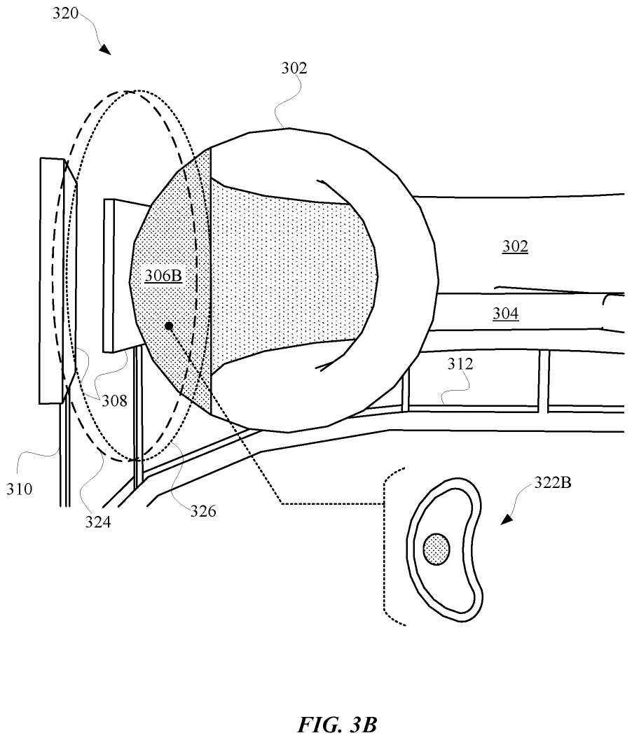

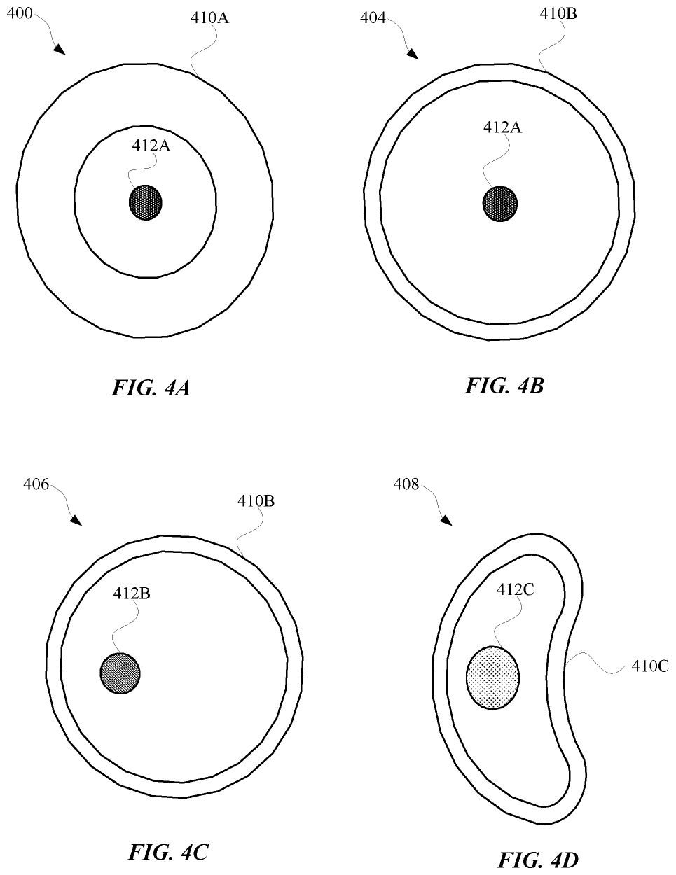

FIG. 3A and FIG. 3B illustrate a cross-sectional view 300 and a cross-sectional view 320 of a system for manipulating mass, such as those described herein. Specifically, FIG. 3A illustrates a cross-sectional view 300 of a material 306A disposed within a material chamber 302, which is at rest in FIG. 3A. However, when the radiation emitting apparatuses 308 are supplied a particular current signal, the material 306A can be forced toward or away from the radiation emitting apparatuses 308 causing the material 306A to relocate. The material 306A can relocate closer to a portion of the material chamber 302 that is closer to the radiation emitting apparatuses 308, as depicted in cross-sectional view 320 of FIG. 3B. Image 322A can provide a view of an atom of the material 306A prior to a first electromagnetic field 324 and a second electromagnetic field 326 affecting the atom of the material. An image 322B can provide another view of the atom of the material 306B, when the first electromagnetic field 324 and the second electromagnetic field 326 are affecting the atom of the material, as further discussed with respect to FIGS. 4A-4D. The first electromagnetic field 324 can oscillate in order to cause the material 306 to increase in temperature, and the second electromagnetic field 326 can cause the material 306 to experience an electromagnetic force that forces the material 306 toward an axis of rotation of the material chamber 302 or away from an axis of rotation of the material chamber 302 (depending on an arrangement of the one or more radiation emitting apparatuses 308).

In some implementations, the material chamber 302 can be caused to spin according to a motor or other spinning apparatus, thereby causing the material 306A to be under a centrifugal force as depicted in FIG. 3B. Each radiation emitting apparatus 308 can be mounted on mounts 310 and/or bracket 312 to form a circular shape having a wider circumference than an outer circumference of the material chamber 302. Alternatively, or additionally, one or more radiation emitting apparatuses 308 can be mounted on mounts 310 and/or bracket 312 to form a circular shape having a smaller circumference than an inner circumference of the material chamber 302. In some implementations, the radiation emitting apparatuses 308 can be mounted exclusively within an inner circumference of the material chamber 302, mounted exclusively outside an outer circumference of the material chamber 302, and/or mounted both inside the inner circumference and outside the outer circumference of the material chamber 302.

FIG. 4A, FIG. 4B, FIG. 4C, and FIG. 4D illustrate a view 400, a view 404, a view 406, and a view 408, respectively, of an atom of material being affected by a system for manipulating mass discussed herein. Specifically, FIG. 4A illustrates a view of a nucleus 412A and electrons 410A (e.g., an electron cloud) of an atom of material located in a material chamber prior to operations of the system for manipulating mass affecting the atom. The nucleus 412A and the electrons 410A can resemble portions of an atom at room temperature and/or otherwise unaffected by operations of the system for manipulating mass. FIG. 4B illustrates a view 404 of the nucleus 412A and the electrons 410B being affected by an increase in temperature within the material chamber of the system for manipulating mass. In some implementations, the system for manipulating mass can cause an increase in temperature within the material chamber by causing an electromagnetic field to interact with atoms of the material within the material chamber. This interaction can cause the atoms to oscillate and/or otherwise move rapidly, resulting in an increase in temperature of the atoms. The increase in temperature of the atoms can be such that the atoms illuminate as a result of photons being emitted from the atoms when electrons 410B of the atom change energy levels. For instance, view 404 illustrates the electrons 410B of an atom in the material chamber having electrons 410 more densely populated at an outer radius region of the atom. This view 404 can provide an example of how more electrons of an atom within the system for manipulating mass can change energy level, emit photons, and populate a greater radius of the atom relative when the atom is not exhibiting an increase in temperature.

FIG. 4C provides a view 406 of an atom being affected by the system for manipulating mass described herein. Specifically, when the electrons 410B are emitting photos as a result transitioning between energy levels as a result of an increase in temperature within the material chamber of the system for manipulating mass, the material chamber can be caused to spin. The spinning of the material chamber, while the atoms of material within the material chamber being heated to a glowing state, can cause a centrifugal and/or inertial force to affect a nucleus of the atoms. For example, as illustrated in FIG. 4C, the nucleus 412B of the atom can shift from a center of the atom, where the nuclear 412A was located in FIG. 4A and FIG. 4B, to a position that is adjacent to the center of the atom. In some implementations, the system for manipulating mass can cause the material chamber to spin in a clockwise direction or a counterclockwise direction while the material within the material chamber is being heated by one or more radiation emitting apparatuses.

As the atoms of the material are being heated and are being spun with the material chamber, one or more other radiation emitting apparatuses can generate a magnetic field for influencing a shape of a “cloud” of electrons 410C. In other words, while the nuclei of the atoms of the material are being shifted according to the inertial force, and while the material chamber is spinning, an electromagnetic field can be employed to pull the electrons 410C in a direction that is the same direction of the inertial force and/or an opposite direction of the inertial force. For example, as provided in view 408, the electromagnetic field acting on the atoms of the material can cause a shape of the “cloud” of electrons 410C to change. The change in shape can result in the “cloud” of electrons affecting nucleus 412C by moving a greater portion of the “cloud” of electrons 410C toward the nucleus 412C and/or causing a field created by a shape of the “cloud” of electrons 410C to affect the nucleus 412C. As a result of the electrons 410C affecting the nucleus 412C, the nucleus 412C can become less dense as a result of electrons influence a balance of charges and/or lack of charges within the nucleus 412C. This change in density of the nucleus 412C can result in changes in properties of the material within the material chamber. Furthermore, such changes in density of the nucleus 412C can be understood in view of how the trend in atomic radius versus atomic number can resemble a wave, as opposed to being entirely proportional. Moreover, changes in density of the nucleus 412C can result in various forces (e.g., gravity, anti-gravity, electromagnetic force, strong interaction force, weak interaction force, etc.) having increased and/or decreased influence over the atoms of the material within the material chamber.

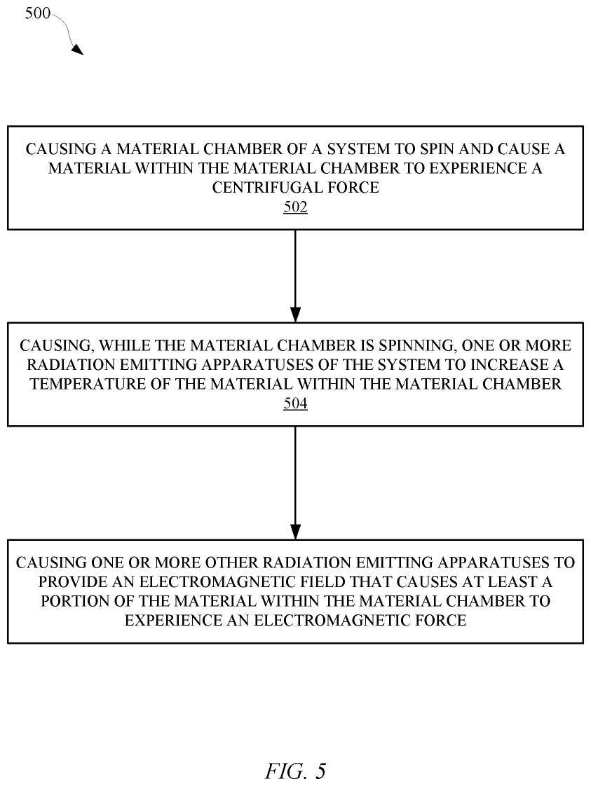

FIG. 5 illustrates a method 500 for controlling a system for manipulating mass. The method 500 can be performed by one or more computing devices, apparatuses, and/or any other application or module capable of controlling an electromechanical device. The method 500 can include an operation 502 of causing a material chamber of the system to spin, wherein a material occupies an inner volume of the material chamber and the material experiences a centrifugal force as a result of the spin of the material chamber.

The method 500 can further include an operation 504 of causing, while the material chamber is spinning, one or more radiation emitting apparatuses to increase a temperature of the material within the material chamber. The increase in temperature of the material occurs when the material is experiencing the centrifugal force resulting from the spinning of the material chamber. The method 500 can further include an operation 506 of causing, while the material is experiencing the increase in temperature and the centrifugal force, one or more radiation emitting apparatuses to provide an electromagnetic field that causes at least a portion of the material within the material chamber to experience an electromagnetic force. The electromagnetic force causes the material to move toward an outer perimeter of the material chamber or toward an inner perimeter of the material chamber. Alternatively, or additionally, the electromagnetic force can cause the material to be forced toward an axis of rotation of the material chamber or away from the axis of rotation of the material chamber.

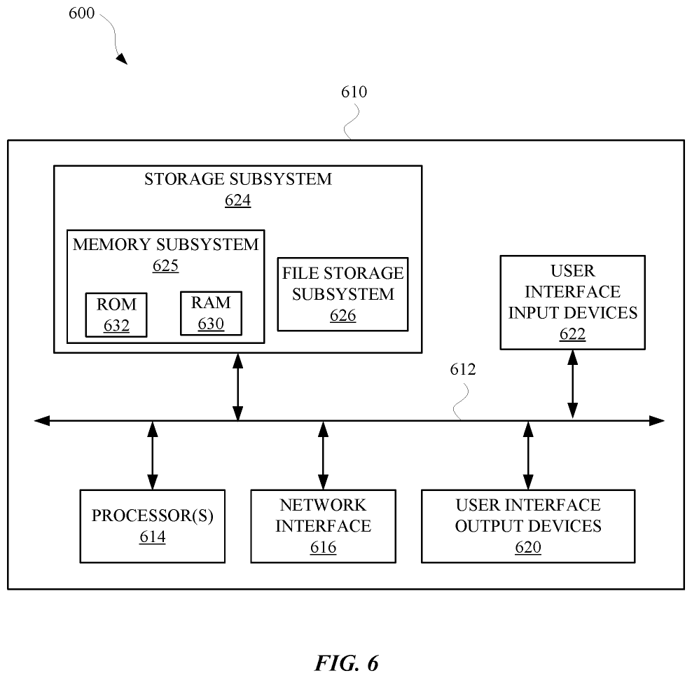

FIG. 6 is a block diagram of an example computer system 610. Computer system 610 typically includes at least one processor 614 which communicates with a number of peripheral devices via bus subsystem 612. These peripheral devices may include a storage subsystem 624, including, for example, a memory 625 and a file storage subsystem 626, user interface output devices 620, user interface input devices 622, and a network interface subsystem 616. The input and output devices allow user interaction with computer system 610. Network interface subsystem 616 provides an interface to outside networks and is coupled to corresponding interface devices in other computer systems.

User interface input devices 622 may include a keyboard, pointing devices such as a mouse, trackball, touchpad, or graphics tablet, a scanner, a touchscreen incorporated into the display, audio input devices such as voice recognition systems, microphones, and/or other types of input devices. In general, use of the term “input device” is intended to include all possible types of devices and ways to input information into computer system 610 or onto a communication network.

User interface output devices 620 may include a display subsystem, a printer, a fax machine, or non-visual displays such as audio output devices. The display subsystem may include a cathode ray tube (CRT), a flat-panel device such as a liquid crystal display (LCD), a projection device, or some other mechanism for creating a visible image. The display subsystem may also provide non-visual display such as via audio output devices. In general, use of the term “output device” is intended to include all possible types of devices and ways to output information from computer system 610 to the user or to another machine or computer system.

Storage subsystem 624 stores programming and data constructs that provide the functionality of some or all of the engines described herein. For example, the storage subsystem 624 may include the logic to perform selected aspects of method 500, and/or to implement one or more of the system for manipulating mass and/or portions of the system for manipulating mass.

These software engines are generally executed by processor 614 alone or in combination with other processors. Memory 625 used in the storage subsystem 624 can include a number of memories including a main random access memory (RAM) 630 for storage of instructions and data during program execution and a read only memory (ROM) 632 in which fixed instructions are stored. A file storage subsystem 626 can provide persistent storage for program and data files, and may include a hard disk drive, a floppy disk drive along with associated removable media, a CD-ROM drive, an optical drive, or removable media cartridges. The engines implementing the functionality of certain implementations may be stored by file storage subsystem 626 in the storage subsystem 624, or in other machines accessible by the processor(s) 614.

Bus subsystem 612 provides a mechanism for letting the various components and subsystems of computer system 610 communicate with each other as intended. Although bus subsystem 612 is shown schematically as a single bus, alternative implementations of the bus subsystem may use multiple busses.

Computer system 610 can be of varying types including a workstation, server, computing cluster, blade server, server farm, or any other data processing system or computing device. Due to the ever-changing nature of computers and networks, the description of computer system 610 depicted in FIG. 6 is intended only as a specific example for purposes of illustrating some implementations. Many other configurations of computer system 610 are possible having more or fewer components than the computer system depicted in FIG. 6.

While several implementations have been described and illustrated herein, a variety of other means and/or structures for performing the function and/or obtaining the results and/or one or more of the advantages described herein may be utilized, and each of such variations and/or modifications is deemed to be within the scope of the implementations described herein. More generally, all parameters, dimensions, materials, and configurations described herein are meant to be exemplary and that the actual parameters, dimensions, materials, and/or configurations will depend upon the specific application or applications for which the teachings is/are used. Those skilled in the art will recognize, or be able to ascertain using no more than routine experimentation, many equivalents to the specific implementations described herein. It is, therefore, to be understood that the foregoing implementations are presented by way of example only and that, within the scope of the appended claims and equivalents thereto, implementations may be practiced otherwise than as specifically described and claimed. Implementations of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

I claim:

1. A system for manipulating mass, the system comprising:
a material chamber configured to at least partially envelope a material;
a motor that is operatively coupled to the material chamber, wherein the motor is configured to directly or indirectly cause the material chamber to rotate;
one or more radiation emitting apparatuses configured to emit a first electromagnetic field and a second electromagnetic field simultaneous to the motor causing the material chamber to rotate,
wherein the first electromagnetic field causes the material within the material chamber to be pulled toward or away from an axis of rotation of the material chamber simultaneous to the material chamber rotating, and
wherein the second electromagnetic field causes the material within the material chamber to exhibit an increase in temperature simultaneous to the material chamber rotating and the material being pulled toward or away from the axis of rotation of the material chamber.

2. The system of claim 1,
wherein an outer perimeter of the material chamber is circular and the one or more radiation emitting apparatuses include a first radiation emitting apparatus and a second radiation emitting apparatus, and
wherein the first radiation emitting apparatus is located outside of an outer radius of the material chamber and the second radiation emitting apparatuses is located outside of the outer radius of material chamber or within the outer radius of the material chamber.

3. The system of claim 1,
wherein an outer perimeter of the material chamber is circular and the one or more radiation emitting apparatuses include a first radiation emitting apparatus and a second radiation emitting apparatus, and
wherein the first radiation emitting apparatus is located within of an outer radius of the material chamber and the second radiation emitting apparatuses is located within the outer radius of the material chamber.

4. The system of claim 1, wherein the second electromagnetic field oscillates according to an input to the second radiation emitting apparatus and causes the material to exhibit the increase in temperature.

5. The system of claim 1, wherein the material is a fluid that includes metal particles.

6. The system of claim 1, wherein the material chamber includes an inner volume that has a torus shape and the material occupies at least a portion of the inner volume.

7. A method implemented by one or more processors for operating a system for manipulating mass, the method comprising:
causing a material chamber of the system to spin,
wherein a material occupies an inner volume of the material chamber and the material experiences a centrifugal force as a result of the spin of the material chamber;
causing, while the material chamber is spinning, one or more radiation emitting apparatuses to increase a temperature of the material within the material chamber,
wherein the increase in temperature of the material occurs when the material is experiencing the centrifugal force resulting from the spinning of the material chamber; and
causing, while the material is experiencing the increase in temperature and the centrifugal force, the one or more other radiation emitting apparatuses to provide an electromagnetic field that causes at least a portion of the material within the material chamber to experience an electromagnetic force,
wherein the electromagnetic force causes the material to move toward an axis of rotation of the material chamber or toward the axis of rotation of the material chamber.

8. The method of claim 7,
wherein an outer perimeter of the material chamber is circular and the one or more radiation emitting apparatuses include a first radiation emitting apparatus and a second radiation emitting apparatus, and
wherein the first radiation emitting apparatus is located outside of an outer radius of the material chamber and the second radiation emitting apparatuses is located outside of the outer radius of material chamber or within the outer radius of the material chamber.

9. The method of claim 7,
Wherein an outer perimeter of the material chamber is circular and the one or more radiation emitting apparatuses include a first radiation emitting apparatus and a second radiation emitting apparatus, and
wherein the first radiation emitting apparatus is located within of an outer radius of the material chamber and the second radiation emitting apparatuses is located within the outer radius of the material chamber or within the outer radius of the material chamber.

10. The method of claim 7, wherein the second electromagnetic field oscillates according to an input to the second radiation emitting apparatus and causes the material to exhibit the increase in temperature.

11. The method of claim 10, wherein the second electromagnetic field causes the material to emit visible light.

12. The method of claim 11, wherein the material is a fluid that includes metal particles.

13. The method of claim 7, wherein the material chamber includes an inner volume that has a torus shape and the material occupies at least a portion of the inner volume.

14. A non-transitory computer readable storage medium configured to store instructions that, when executed by a processor included in a computing device, cause the computing device to perform operations that include:
causing a material chamber of the system to spin,
wherein a material occupies an inner volume of the material chamber and the material experiences a centrifugal force as a result of the spin of the material chamber;
causing, while the material chamber is spinning, one or more radiation emitting apparatuses to increase a temperature of the material within the material chamber,
wherein the increase in temperature of the material occurs when the material is experiencing the centrifugal force resulting from the spinning of the material chamber; and
causing, while the material is experiencing the increase in temperature and the centrifugal force, the one or more other radiation emitting apparatuses to provide an electromagnetic field that causes at least a portion of the material within the material chamber to experience an electromagnetic force,
wherein the electromagnetic force causes the material to move toward an outer perimeter of the material chamber or toward an inner perimeter of the material chamber.

15. The non-transitory computer readable storage medium of claim 14,
wherein the outer perimeter is circular and the one or more radiation emitting apparatuses include a first radiation emitting apparatus and a second radiation emitting apparatus, and
wherein the first radiation emitting apparatus is located outside of an outer radius of the material chamber and the second radiation emitting apparatuses is located outside of the outer radius of material chamber or within the outer radius of the material chamber.

16. The non-transitory computer readable storage medium of claim 14,
wherein the outer perimeter is circular and the one or more radiation emitting apparatuses include a first radiation emitting apparatus and a second radiation emitting apparatus, and
wherein the first radiation emitting apparatus is located within of an outer radius of the material chamber and the second radiation emitting apparatuses is located within the outer radius of the material chamber or within the outer radius of the material chamber.

17. The non-transitory computer readable storage medium of claim 14, wherein the second electromagnetic field oscillates according to an input to the second radiation emitting apparatus and causes the material to exhibit the increase in temperature.

18. The non-transitory computer readable storage medium of claim 17, wherein the second electromagnetic field causes the material to emit visible light.

19. The non-transitory computer readable storage medium of claim 18, wherein the material is a fluid that includes metal particles.

20. The non-transitory computer readable storage medium of claim 14, wherein the material chamber includes an inner volume that has a torus shape and the material occupies at least a portion of the inner volume.
